(19) United States
(12) Patent Application Publication
(10) Pub. No.: US 2018/0363142 A1
(43) Pub. Date: Dec. 20, 2018

(54) Method for simultaneous plasma edge encapsulation of at least two adhesive tape sides

(71) Applicant: TESA SE, Norderstedt (DE)

(72) Inventors: Manuel BENDEICH, Hamburg (DE); Arne KOOPS, Neu-Lankau (DE)

(21) Appl. No.: 16/003,834

(22) Filed: Jun. 8, 2018

(30) Foreign Application Priority Data
Jun. 14, 2017 (DE) 10 2017 210 066.4

(51) Int. Cl. C23C 16/513; C23C 16/40; C23C 16/455

(52) U.S. Cl. CPC C23C 16/513; C23C 16/45591; C23C 16/401

(57) ABSTRACT

The invention relates to a method for plasma treatment of at least one surface, wherein a plasma stream (7a) is guided from a plasma nozzle (1) and at least one surface is disposed outside a stream-directionally extended opening cross section of an opening (21) in the plasma nozzle (1), and the plasma stream (7a) is diverted onto the at least one surface.

This application claims foreign priority benefit of German Application No. DE 10 2017 210 066.4, filed Jun. 14, 2017, the disclosure of which patent application is incorporated herein by reference.

The invention relates to a method for the plasma treatment of at least one surface. The invention also relates to an arrangement having at least one surface and a device for the plasma treatment of the at least one surface.

With adhesive tape rolls, especially of the ACXP^{plus} range from tesa SE, a disadvantage which has been found is that on stacking or on contact with other articles, the adhesive tape sides display a tendency to stick. To counteract this unwanted effect, siliconized side discs are typically placed onto the end face of the roll. In the case of ACXP^{plus} products, two side discs are used per roll for safety; in the case of filmic products, just one side disc is enough. These discs at the same time prevent contamination by particles which bind to the pressure-sensitive adhesive during transport or processing. Where such side discs are used, they must be finished appropriately for roll dimensions and packaging. For processing by machine and by hand, the side disc requires subsequent removal, and replacement on the end face after use. All in all, the utilization of siliconized side inserts implies a not inconsiderable labour cost and effort.

A variety of solutions are already in existence for the deactivation of the tackiness on the adhesive tape sides.

The adhesive tape side is treated by pressurized powdering, so that applied talc or applied glass beads lead to a reduction in the peel adhesion. This process is detrimental to the optical properties of the adhesive tape roll. Moreover, there is contamination owing to a few firmly adhering talc particles, this being undesirable in numerous applications. At the same time, the long-term stability of the deactivation is not assured, since at higher temperatures the particles applied sink into or become surrounded by the adhesive.

As a further solution, the coating of the adhesive tape side is undertaken with a conventional varnish. Here, processing times are very long owing to the need for drying. At the same time, for high application rates of 3 g/m², for example, relatively high unwind forces are observed.

Adding water to the varnish reduces the formation of a film, allowing the unwind forces to be reduced to a normal level.

WO 2008/095653 A describes a method for passivating an edge of pressure-sensitive adhesive tapes, in which the passivation is accomplished by physical or chemical crosslinking of the pressure-sensitive adhesive on the edge or by the physical or chemical breakdown of the structures in the pressure-sensitive adhesive that are responsible for the adhesive effect. This is achieved by applying a crosslinker to the adhesive tape side, with subsequent UV or IR irradiation, electron irradiation, gamma irradiation or plasma treatment. Crosslinkers disclosed include epoxides, amines, isocyanates, peroxides or polyfunctional silanes. A disadvantage is the relatively awkward and inconvenient structure of the method.

EP 1 373 423 describes a method for deactivating the adhesive layer of the edge face of a roll of adhesive tape, by applying radiation-crosslinkable acrylates, acrylate oligomers and acrylate prepolymers, and carrying out curing with ionizing and electromagnetic radiation.

US 2010/004 47 530 describes a method for coating the adhesive tape sides of an adhesive tape roll, using an indirect application method, in which radiation-curable varnishes or hot-melting polymers are employed.

EP 1 129 791 A2 describes a method for producing anti-adhesive coatings wherein the anti-adhesive layer is applied by low-pressure plasma polymerization to the material in web form, this material in web form being drawn continuously through a plasma zone which hosts a low-pressure plasma. The anti-adhesive coatings, shaped by means of plasma polymerization, are produced in particular for reverse sides of adhesive tape and for release materials.

Disadvantageous aspects of the direct plasma treatment of adhesive tapes are in particular that the plasma has high temperatures of 200° C.-250° C. and both the layer of adhesive and the carrier material of the adhesive tape are exposed to a thermal input which may destroy them.

It is an object of the present invention, therefore, to provide a method and an arrangement that allow more gentle plasma treatment of surfaces.

The object is achieved with regard to the method by a method having the features as described herein.

In accordance with the invention a plasma stream is guided from a plasma nozzle, and the at least one surface is disposed outside an opening cross section of the plasma nozzle, this cross section being extended preferably consistently in the stream direction, and the plasma stream is diverted onto the at least one surface.

The surface is preferably a surface of a layer of adhesive. The layer of adhesive may have been applied to a carrier film, and together they form the adhesive tape. The adhesive tape may of course comprise a greater number of layers than the two which have been identified.

In accordance with the invention, the at least one surface to be treated is not exposed directly to the plasma stream coming from the plasma nozzle; instead, the plasma stream is diverted beforehand. The diverted plasma stream that then strikes the at least one surface has considerably less thermal energy than the plasma stream striking directly on the at least one surface. The diverted plasma stream is no longer able to cause thermal destruction of the at least one surface. Surprisingly it has emerged that the activation brought about by the plasma stream to the at least one surface is retained, and likewise, when a precursor is supplied into the plasma stream, even after the diverting of the plasma stream, the passivating properties of the plasma stream, through the application of a passivation coat to the surface, are retained.

Surfaces can be activated by plasma treatments, by exciting and ionizing a process gas which among others may in particular be air by means of an electrical field and leading the excited gas onto the surface.

The process gas may be admixed with precursors, these being, in particular, gaseous compounds such as siloxane, acrylic acid or solvents, or else other constituents. Precursors may bring about coating of the activated surface.

In the context of plasma treatment, a distinction is made between the direct corona treatment and the indirect plasma treatment proper. Corona treatment is defined as a surface treatment with filamentary discharges that is generated between two electrodes by means of high alternating voltage, with the discrete discharge channels striking the surface to be treated (in this regard see also Wagner et al., Vacuum 71, 2003, pp. 417-436. The process gas used may be, in particular, ambient air. In the case of corona treatment, the substrate to be treated in the present case, the at least one surface to be treated is almost always placed in or guided through the discharge space between an electrode and a counter-electrode, this being defined as “direct” for the physical treatment. Substrates in web form are typically guided through between an electrode and an earthed roller. In industrial applications in particular, the term “corona” usually refers to electrical barrier discharge. In that case, at least one of the electrodes consists of a dielectric, in other words an insulator, or is coated or covered with a dielectric. In particular, the substrate in this case may also act as the dielectric. Also possible in addition, however, is a uniform, more intense corona treatment of materials of different kinds, shapes and thicknesses, in which the corona effect on the surface of the material to be treated is avoided completely. In EP 0497996 B1, for example, a dual-pin electrode is selected, with each pin electrode having its own channel for pressurization. Between the two tips of the electrodes, there is a corona discharge, which ionizes the gas stream flowing through the channels and converts it into a plasma. This plasma then passes to the surface to be treated, where in particular it performs a surface oxidation that enhances the usability of the surface. The nature of the physical treatment is referred to in our context as “indirect” because the treatment is not performed at the location where the electrical charge is generated. Hereinafter, preference will be given to assuming an indirect plasma corona treatment when referring to a plasma treatment, though this is not necessarily the case. The treatment of the surface takes place preferably at or close to atmospheric pressure, although the pressure between discharge space or gas channel may be increased, and particularly in the scenarios present here, when using ambient air as process gas, the air may also be forced through the process gas channel with a pressure of 5 to 6 bar. The electrical discharges, along with processes of ionization in the electrical field, cause the gas to be activated, generating highly excited states in gas constituents. The gas used is referred to as process gas. As already mentioned above, the process gas may also have precursors admixed. Among the species formed in the plasma are electrons and ions. They strike the surface with energies which are sufficient to break the majority of molecular bonds. The reactivity of the reactive gas constituents that are also formed is mostly a subordinate effect. The broken bond sites then react further with constituents of the air or of the process gas, and in particular they may undergo further reaction with the precursors.

Indirect plasma treatment therefore differs from corona treatment in particular in the fact that in the case of plasma treatment there is no direct exposure of the surface to the discharge channels. The effect, then, occurs homogeneously and gently, above all by way of reactive gas constituents. In the case of indirect plasma treatment, there are possibly free electrons present, though they are not accelerated, since the treatment takes place outside the generating electrical field.

The plasma apparatus of EP 0 497 996 B1 features decidedly high gas streams in the region of 36 m³/hour, with a 40 cm electrode width per gap. The high flow rates result in a low residence time of the activated constituents on the surface of the substrate. Moreover, the only plasma constituents reaching the substrate are those which have a correspondingly long life and can be moved by a gas stream; electrons, for example, cannot be moved by a gas stream and play no part in this form of plasma treatment.

A disadvantage associated with the plasma treatment, however, is the fact that the plasma striking the substrate surface has high temperatures of, in the best case, at least 120° C., though the plasma in question frequently possesses high temperatures of several 100° C. The known plasma nozzles lead to a high thermal input into the at least one surface. The high temperatures may cause damage to the substrate surface, producing not only the activating products but also unwanted by-products known as LMWOMs (low molecular weight oxidized materials). This highly oxidized and water-soluble polymer dross, which is no longer covalently joined to the substrate, results in a low resistance towards ambient conditions of heat and humidity.

Surprisingly it has now emerged that by deflection of a plasma stream emerging from a plasma nozzle, it is possible for a surface to be plasma treated, more particularly activated by plasma, with the plasma stream having a much lower temperature, by virtue of the greater distance and the diversion of the plasma stream, than in those cases where the surface to be treated is disposed directly beneath the plasma nozzle, i.e. beneath the opening cross section of the plasma nozzle.

In one preferred embodiment of the invention, the plasma stream emerging from the opening is diverted at an impact face and steered onto a surface which is disposed transversely to the cross-sectional area of the opening. The impact face may be a horizontal, preferably metallic, surface, or else a spherical, hemispherical or sphere-segment-shaped surface, on which the plasma stream impinges from the opening in the plasma nozzle and can readily be parted and diverted into different directions as well. The baffles may also consist of different materials on their surface on which the plasma stream strikes. A part or the entire diverted plasma stream then strikes the at least one surface to be treated, this surface being disposed transversely, preferably likewise perpendicularly to the cross-sectional area of the opening, by virtue of the diversion, which takes place preferably at an angle of 90°±10°, more preferably ±5°, although any other angle, especially one between the indicated angles, may be envisaged and is hereby also disclosed. Transversely here means that the cross-sectional area of the opening exhibits a surface normal, and the at least one surface to be treated likewise exhibits a surface normal. The two surface normals, however, are not parallel to one another, but instead are at an angle to one another, preferably perpendicularly, they may, however, also have an angle of 90°±10°, more preferably ±5°, to one another, with all angles in between being likewise disclosed.

With particular preference the plasma stream can be parted at a baffle and the parted plasma streams can be diverted simultaneously into different directions, and each of the parted plasma streams is diverted onto a different surface. As a result it is possible with a single plasma nozzle to treat, simultaneously, two surfaces or any higher number of surfaces with plasma.

Particular preference is given to using an adhesive tape having an adhesive face and at least one, preferably two, adhesive tape side(s). The two adhesive tape sides extend oppositely along two adhesive face edges of the adhesive face. With preference at least one of the adhesive tape sides of the adhesive tape is used as at least one surface, and the adhesive tape side is disposed perpendicularly to the cross-sectional area of the opening. In this case as well, the adhesive tape side of the adhesive tape may be disposed in other angular arrangements which have been stated above.

This method is therefore particularly favourable because it is possible to carry out plasma treatment and coating of a conventional adhesive tape having one adhesive side along one or, preferably, both adhesive tape side(s). The adhesive tape sides are therefore passivated, and after the passivation are no longer pressure-sensitively tacky. For this purpose, the adhesive side of the adhesive tape is lined with a liner, and the adhesive tape is drawn through parallel to the opening cross section of the plasma nozzle, but, in accordance with the invention, not directly below the plasma nozzle, being instead moved along adjacent to the plasma nozzle, preferably at a continuous, constant speed, and the plasma stream emerging from the plasma nozzle is diverted at the baffle and then strikes only against the adhesive tape side of the adhesive tape. Because it is lined with the liner, the adhesive side of the adhesive tape is not plasma-treated. The plasma treatment of the adhesive tape side enables a significant reduction to be achieved in the peel adhesion of the adhesive tape side, so that an adhesive tape later wound into a roll has an end face which is no longer sticky.

It is possible to treat both adhesive tape sides of the adhesive tape with plasma simultaneously, for which purpose the plasma stream can be parted and the preferably two part-streams may be steered onto the two adhesive tape sides.

Alternatively for this purpose, the adhesive tape is disposed between two plasma nozzles, and each of the two adhesive tape sides is disposed outside a flow-directionally extended opening cross section of an assigned plasma nozzle. Through an arrangement of a series of plasma nozzles, therefore, it is also possible to passivate a plurality of adhesive tapes at the same time, in other words to passivate both adhesive tape sides of two or more adhesive tapes simultaneously.

With particular preference, the plasma stream is used to apply an activation coat to the at least one surface, more particularly to the adhesive tape sides of the adhesive tape. The plasma stream is preferably supplied with an organic precursor comprising polyfunctional silanes. The plasma stream enriched with the precursor is directed onto at least one surface and the at least one surface is covered with an SiOx coating. In accordance with the invention, however, the plasma stream is not directed directly onto the at least one adhesive tape side, but instead onto the baffle, by which the plasma stream is deflected and only after diversion is steered onto the at least one surface, more particularly adhesive tape side. An SiOx coating is applied preferably over the whole area of the adhesive tape side. The coating favourably has a thickness which is constant over the entire extent of the adhesive tape side, the coating being preferably between 60 nm to 600 nm thick, the thickness lying preferably between 100 nm and 200 nm. A precursor used is, favourably, hexamethyldisiloxane (HMDSO), which is supplied to the process gas in an order of magnitude of 10, 20, 40 to 150 grams per hour. The HMDSO is vaporized in a vaporizer at about 120° C.; the precursor gas issuing from the vaporizer is supplied to a nozzle head, where it is mixed with the process gas. With the plasma, then, the precursor reaches the surface to be treated. Instead of HMDSO it is also possible, however, to use (3-glycidyloxypropyl)trimethoxysilane (GLYMO) and octyltriethoxysilane (OCS), with polyfunctional silanes being preferably used.

Suitable material for carrier films includes, for example, PA, PU or PVC, polyolefins or polyester, preferably a polyester comprising PET (polyethylene terephthalate). The film itself may consist in turn of a plurality of individual plies, as for example of plies coextruded to form film.

Preference is given to using polyolefins, though also included are copolymers of ethylene and polar monomers such as styrene, vinyl acetate, methyl methacrylate, butyl acrylate or acrylic acid. The compound in question may be a homopolymer such as HDPE, LDPE or MDPE, or a copolymer of ethylene or another olefin such as propene, butene, hexene or octene (for example LLDPE or VLDPE). Also suitable are polypropylenes (for example polypropylene homopolymers, random polypropylene copolymers or polypropylene block copolymers).

Outstandingly useful as films in accordance with the invention are monoaxially and biaxially oriented films. Monoaxially oriented polypropylene, for example, is notable for its very high tear resistance and low elongation in machine direction. Particularly preferred are films based on polyesters, especially those comprising PET polyethylene terephthalate.

The film preferably has a thickness of 12 μm to 100 μm, more preferably of 28 to 50 μm, more particularly 35 μm.

Provided on one side of the carrier film is a layer of adhesive that preferably covers the full area of the side of the carrier film. All known adhesive systems can be used.

Besides adhesives based on natural or synthetic rubber, use may be made in particular of silicone adhesives and also of polyacrylate adhesives, preferably a low molecular mass, pressure-sensitive, acrylate hotmelt adhesive. The latter are described in more detail in DE 198 07 752 A1 and also in DE 100 11 788 A1.

The laminating adhesive that may be present may be selected from the same adhesive systems.

The coat weight is situated preferably within the range between 15 to 200 g/m², more preferably between 30 to 120 g/m², very preferably at 80 g/m² (corresponding approximately to a thickness of 15 to 200 μm, more preferably of 30 to 120 μm, very preferably of 80 μm).

The adhesive is preferably a pressure-sensitive adhesive, in other words a viscoelastic composition which at room temperature in the dry state remains permanently tacky and adhesive. Bonding is accomplished by gentle applied pressure immediately on virtually all substrates.

Pressure-sensitive adhesives employed include those based on block copolymers containing polymer blocks. These blocks are formed preferably of vinylaromatics (A blocks), such as styrene, for example, and through polymerization of 1,3-dienes (B blocks), such as, for example, butadiene and isoprene, or a copolymer of the two. Mixtures of different block copolymers can also be employed. Preference is given to using products which are partly or fully hydrogenated.

The block copolymers may have a linear A-B-A structure. It is likewise possible to employ block copolymers with radial architecture, and also star-shaped and linear multiblock copolymers.

In place of the polystyrene blocks it is also possible to utilize polymer blocks based on other aromatics-containing homopolymers and copolymers (preferably C8 to C12 aromatics), having glass transition temperatures of >about 75° C., such as, for example, -methylstyrene-containing aromatics blocks. Also utilizable are polymer blocks based on (meth)acrylate homopolymers and (meth)acrylate copolymers with glass transition temperatures of >+75° C. In this context it is possible to employ not only block copolymers which as hard blocks utilize exclusively those based on (meth)acrylate polymers, but also those which utilize not only polyaromatics blocks, polystyrene blocks for example, but also poly(meth)acrylate blocks.

The figures for the glass transition temperature for materials which are not inorganic and not predominantly inorganic, more particularly for organic and polymeric materials, relate to the glass transition temperature figure Tg in accordance with DIN 53765:1994-03 (cf. section 2.2.1), unless indicated otherwise in the specific case.

In place of styrene-butadiene block copolymers and styrene-isoprene block copolymers and/or their hydrogenation products, including styrene-ethylene/butylene block copolymers and styrene-ethylene/propylene block copolymers, it is likewise possible in accordance with the invention to utilize block copolymers and their hydrogenation products which utilize further polydiene-containing elastomer blocks such as, for example, copolymers of two or more different 1,3-dienes. Further utilizable in accordance with the invention are functionalized block copolymers such as, for example, maleic anhydride-modified or silane-modified styrene block copolymers.

Typical use concentrations for the block copolymer lie at a concentration in the range between 30 wt % and 70 wt %, more particularly in the range between 35 wt % and 55 wt %.

Further polymers that may be present are those based on pure hydrocarbons such as, for example, unsaturated polydienes, such as natural or synthetically produced polyisoprene or polybutadiene, elastomers with substantial chemical saturation, such as, for example, saturated ethylene-propylene copolymers, -olefin copolymers, polyisobutylene, butyl rubber, ethylene-propylene rubber, and also chemically functionalized hydrocarbons such as, for example, halogen-containing, acrylate-containing, or vinyl ether-containing polyolefins, which may replace up to half of the vinylaromatics-containing block copolymers.

Serving as tackifiers are tackifier resins.

Suitable tackifier resins include preferably partially or fully hydrogenated resins based on rosin or on rosin derivatives. It is also possible at least in part to employ hydrogenated hydrocarbon resins, examples being hydrogenated hydrocarbon resins obtained by partial or complete hydrogenation of aromatics-containing hydrocarbon resins (for example, Arkon P and Arkon M series from Arakawa, or Regalite series from Eastman), hydrocarbon resins based on hydrogenated dicyclopentadiene polymers (for example, Escorez 5300 series from Exxon), hydrocarbon resins based on hydrogenated C5/C9 resins (Escorez 5600 series from Exxon), or hydrocarbon resins based on hydrogenated C5 resins (Eastotac from Eastman), and/or mixtures thereof.

Hydrogenated polyterpene resins based on polyterpenes can also be used. Aforementioned tackifier resins may be employed both alone and in a mixture.

Further additives that can be used include, typically, light stabilizers such as, for example, UV absorbers, sterically hindered amines, antiozonants, metal deactivators, processing assistants, and endblock-reinforcing resins.

Plasticizers such as, for example, liquid resins, plasticizer oils, or low molecular mass liquid polymers such as, for example, low molecular mass polyisobutylenes with molar masses <1500 g/mol (numerical average) or liquid EPDM grades are typically employed.

The invention in its second aspect is fulfilled by an arrangement identified at the outset and having the features as described herein.

The arrangement comprises the at least one surface and a device for passivating the at least one surface. The device for passivating the at least one surface comprises a plasma nozzle having an opening with an opening cross section, the at least one surface being disposed outside an opening cross section of the plasma nozzle that is extended in the flow direction, but is preferably of consistent size, and a baffle which is disposed in front of the opening in such a way that the plasma stream is diverted at least partly onto the at least one surface. The arrangement according to the invention is especially suitable for implementing one of the methods stated above, and the above-stated methods can be implemented with the arrangement described.

In accordance with the invention, a conventional plasma nozzle may be a constituent of the arrangement, though in accordance with the invention the at least one surface which is treated with the plasma stream emerging from the plasma nozzle is disposed not, in the conventional way, directly beneath the opening cross section of the plasma nozzle, but instead adjacent to the opening cross section. If the preferably circular opening cross section is extended in the flow direction of the plasma, the extension thus favourably forming a cylindrical body, the surface to be treated, thus in particular the adhesive tape side of an adhesive tape, is disposed outside this flow-directionally extended cross section of the plasma nozzle. Of course, the opening cross section could also be rectangular and the extension could therefore be cuboidal. Many other forms of the opening cross section are also conceivable.

The plasma stream emerging from the plasma nozzle strikes the surface to be treated not directly but instead only after diversion. The baffle is preferably designed so that it parts the plasma stream, and different partial plasma streams are directed onto different surfaces. For this purpose the baffle may be formed, in particular in cross section perpendicularly to the flow direction of the plasma stream, triangularly or spherically or semi-circularly, and the baffle may also be pyramidal, tetrahedral or hemispherical in form, so that the plasma stream striking the baffle, with a diameter of preferably about 4 mm, corresponds to the diameter of the opening in the plasma nozzle and is diverted into a different direction depending on the point at which it strikes.

The invention is described by means of an exemplary embodiment in two figures, of which

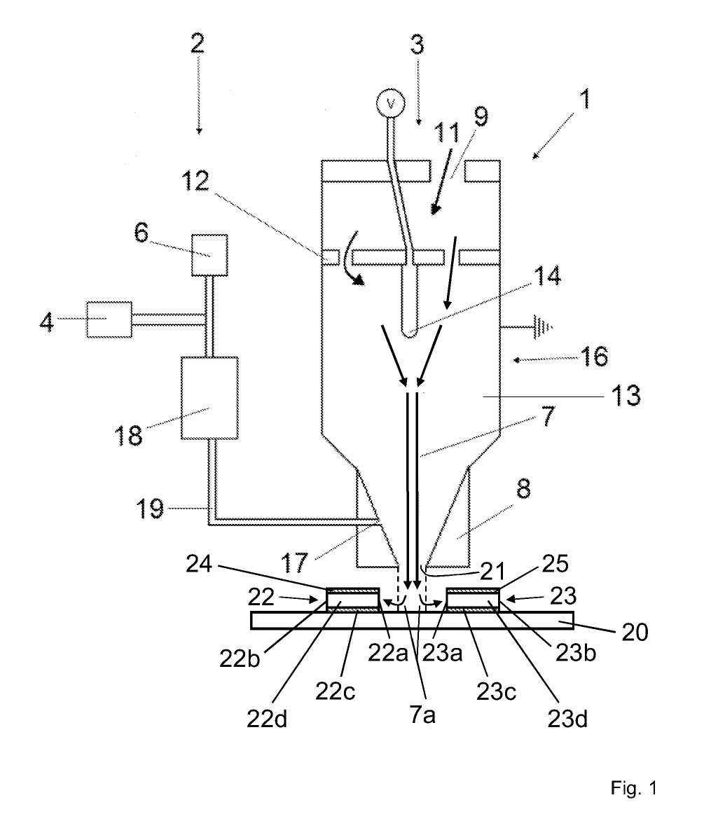

FIG. 1 shows a frontal view of an arrangement according to the invention for the simultaneous passivation of two adhesive tape sides, and

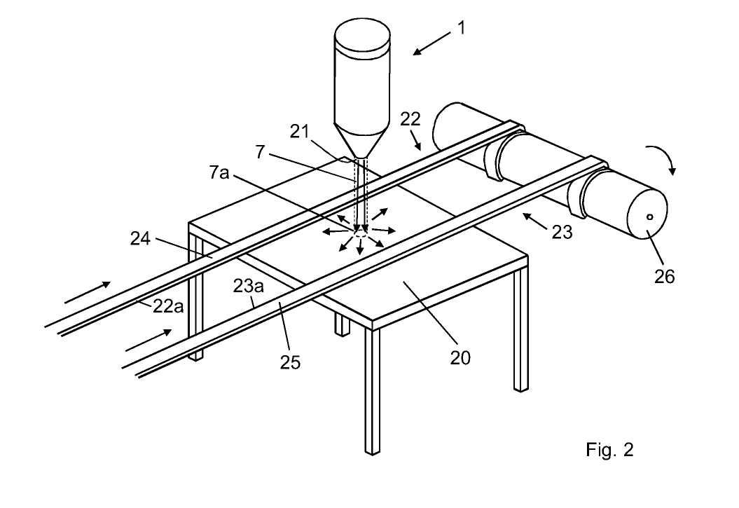

FIG. 2 shows a perspective view of the arrangement in FIG. 1.

FIG. 1 shows a plasma nozzle 1. The plasma nozzle 1 comprises a precursor unit 2, which in FIG. 1 is shown on the left, and a plasma unit 3, which in FIG. 1 is shown on the right. The precursor unit 2 generates a carrier gas 6 enriched with a precursor 4, while the plasma unit 3 generates a plasma 7. The precursor 4 and the plasma 7 are merged in a nozzle head 8.

The plasma 7 here is a high-energy process gas 11, more particularly ionized air. To generate the plasma 7, the plasma unit 3 is first supplied through an inlet 9 with the process gas 11. The process gas 11 is introduced through the inlet 9 into the plasma unit 3 and passes, through a plate 12 with drilled holes, into a discharge zone 13, through which the process gas 11 flows. In the discharge zone 13, the process gas 11 is conveyed past an electrode tip 14, to which a high-frequency alternating voltage of several kilovolts with a frequency of around 10 kilohertz is connected. Between the electrode tip 14 and a counter-electrode, which may for example be an earthed stainless steel housing 16, a strong alternating electrical field is formed that leads to a corona discharge, which ionizes the process gas 11 flowing through the plasma unit 3 past the electrode tip 14, and converts it into a plasma stream 7a. The plasma 7 is guided through the nozzle head 8, to which the precursor unit 2 is connected at a side inlet 17. The side inlet 17 of the nozzle head 8 is joined to the precursor unit 2. The precursor unit 2 comprises a first feed for the precursor 4 and a second feed for the carrier gas 6. The carrier gas 6 used here may likewise be air or else nitrogen or else a mixture of air and nitrogen. The precursor 4 is atomized and supplied to the carrier gas 6 in droplet form. The mixture passes into a vaporizer 18, where temperatures above the boiling point of the precursor 4 prevail. The precursor 4 used may be an organic, polyfunctional silane, examples being octyltriethoxysilane (OCS), (3-glycidyloxypropyl)trimethoxysilanes (GLYMO) and hexamethyldisiloxane (HMDSO).

The precursor 4 used here is hexamethyldisiloxane (HMDSO), which is supplied to the carrier gas 6 in an order of magnitude of 10, 20 or 40 grams per hour. The temperature in the vaporizer 18 is 120° C., in other words above the boiling temperature of HMDSO, which is about 100° C. A precursor gas 19 issuing in the vaporizer 18 is supplied to the nozzle head 8, where it is combined with the plasma; accordingly, together with the plasma 7, the precursor 4 passes out of the plasma nozzle 1 and flows onto a baffle 20. The baffle 20 takes the form here of a planar steel plate. At the steel plate, the plasma stream 7a with the admixed precursor 4 is diverted, and in particular the plasma 7 flows away to the side along the baffle 20. An opening 21 in the plasma nozzle 1 is formed circularly in a cross section perpendicular to the stream direction of the plasma 7, and has a diameter of 4 mm. A cross-sectional area of the opening 21 is disposed horizontally and disposed parallel to the impact face of the baffle 20. A cross-sectional area of the plasma nozzle 1 that is extended in the flow direction of the plasma 7 is therefore cylindrical in form. The extended cross-sectional area is indicated in FIG. 1 and FIG. 2 by means of dashed lines.

It is essential to the invention here that two adhesive tapes 22, 23 disposed parallel to one another and at a distance from one another are provided, these tapes being disposed laterally adjacent to the extended cross-sectional area of the plasma nozzle 1; in other words, the plasma stream 7a emerging directly from the opening 21 strikes the adhesive tapes 22, 23 not directly; instead, inner adhesive tape sides 22a, 23a of the two adhesive tapes 22, 23 are struck simultaneously by the diverted plasma stream 7a and passivated. In this arrangement, outer adhesive tape sides 22b, 23b of the two adhesive tapes 22, 23 are not passivated.

The two adhesive tapes 22, 23 each have a carrier film 22c, 23c and also each have a layer 22d, 23d of adhesive, which in FIG. 1 is shown somewhat thicker than is usual. An adhesive side of the layer 22d, 23d of adhesive that is used later on for the actual bonding is lined in each case with a liner 24, 25; the liner 24, 25 protects the adhesive side of the adhesive tape 22, 23 from the emerging and diverted plasma stream 7a. The only sides therefore exposed to the diverted plasma stream 7a are the open-lying inner adhesive tape sides 22a, 23a of the two adhesive tapes 22, 23.

FIG. 2 shows the arrangement of FIG. 1 in a perspective view. The two simultaneously treated adhesive tapes 22, 23 are wound up to a roll 26 and drawn at a consistent speed over the deflection face of the steel plate. The adhesive tapes here are guided in guides which are not illustrated here; sections of the inner adhesive tape sides 22a, 23a of the two adhesive tapes 22, 23 are treated simultaneously with the plasma stream 7a during the entire time.

Each of the two adhesive tapes 22, 23 is formed in each case by a carrier film 22c, 23c and a layer 22d, 23d of adhesive. The carrier film 22c, 23c is provided in different widths and in the width provided is coated over the full area with the layer 22d, 23d of adhesive. When the adhesive tape 22, 23 is wound up, the tacky adhesive tape sides 22a, 22b, 23a, 23b of the layer 22d, 23d of adhesive on the adhesive tape 22, 23 lie open. They make it more difficult for the product to be used; they may stick, and foreign particles may become deposited on them.

The tackiness of the inner adhesive tape sides 22a, 23a is reduced by application of a passivation coat; the passivation coat may be an SiOx coating which is applied over the full area to the inner adhesive tape sides 22a, 23a of the layers 22d, 23d of adhesive on the adhesive tape 22, 23 in a plasma process, using the plasma nozzle 1 shown in FIGS. 1 and 2. In this case, the opening cross section of the plasma nozzle 1 lies perpendicular to the inner adhesive tape sides 22a, 23a of the layers 22d, 23d of adhesive.

The adhesive may be a pressure-sensitive adhesive, more particularly an acrylic adhesive. The substrate web may be a PET or PE film.

### LIST OF REFERENCE SYMBOLS

1 Plasma nozzle

2 Precursor unit

3 Plasma unit

4 Precursor

6 Carrier gas

7 Plasma

7a Plasma stream

8 Nozzle head

9 Inlet

11 Process gas

12 Plate

13 Discharge zone

14 Electrode tip

16 Earthed stainless steel housing

17 Side inlet

18 Vaporizer

19 Precursor gas

20 Baffle

21 Opening

22 Adhesive tape

22a Inner adhesive tape side

22b Outer adhesive tape side

22c Carrier film

22d Layer of adhesive

23 Adhesive tape

23a Inner adhesive tape side

23b Outer adhesive tape side

23c Carrier film

23d Layer of adhesive

24 Liner

25 Liner

26 Roll

1. A method for plasma treatment of at least one surface, wherein
a plasma stream is guided from a plasma nozzle and at least one surface is disposed outside a stream-directionally extended opening cross section of an opening in the plasma nozzle, and the plasma stream is diverted onto the at least one surface.

2. The method according to claim 1,
the plasma stream emerging from the opening is diverted at a baffle and the at least one surface is disposed transversely to the cross-sectional area of the opening.

3. The method according to claim 1,
the plasma stream is parted at a baffle and the parted plasma streams are diverted simultaneously into different directions and each of the parted plasma streams is steered onto a different surface.

4. The method according to claim 1, wherein
an adhesive tape having a layer of adhesive is used which comprises at least one adhesive tape side, the adhesive tape side is disposed perpendicularly to the cross-sectional area of the opening and plasma treatment is performed.

5. The method according to claim 1, wherein
the adhesive tape has two sides and the two adhesive tape sides are treated simultaneously with plasma.

6. The method according to claim 1, wherein
the adhesive tape having two adhesive tape sides is disposed between two plasma nozzles and each of the two adhesive tape sides of the adhesive tape is disposed in each case outside both stream-directionally extended opening cross sections of the plasma nozzles.

7. The method according to claim 1, wherein
the adhesive tape side has pressure-sensitive tack and the plasma stream applies a passivation coat to the adhesive tape side.

8. The method according to claim 1, wherein
the adhesive tape is used with one adhesive side and two adhesive tape sides, and one adhesive side of the adhesive tape is lined, and only the adhesive tape sides are passivated.

9. The according to claim 1, wherein
the at least one surface is covered with an SiOx coating.

10. An arrangement having at least one surface and a device for the plasma treatment of the at least one surface with a plasma nozzle having an opening with an opening cross section, wherein
the at least one surface is disposed outside a flow-directionally extended opening cross section of the plasma nozzle and a baffle is disposed in front of the opening in such a way that a plasma stream is diverted at least partly onto the at least one surface.

11. The arrangement according to claim 10, wherein
the baffle parts the plasma stream and different parted plasma streams are directed onto different surfaces.

12. The arrangement according to claim 10, wherein
the opening is circular and has a diameter of 4 mm.
